(19) United States
(12) Patent Application Publication
(10) Pub. No.: US 2026/0085445 A1
(43) Pub. Date: Mar. 26, 2026

(54) FLOW GUIDE ARRANGEMENTS FOR GAS ACTIVATION AND GAS DISTRIBUTION, AND RELATED CHAMBER KITS, METHODS, AND PROCESSING CHAMBERS

(71) Applicant: Applied Materials, Inc., Santa Clara, CA (US)

(72) Inventors: Zhepeng CONG, San Jose, CA (US); Himani ARORA, Albany, CA (US); Chen-Ying WU, Santa Clara, CA (US)

(21) Appl. No.: 18/893,646

(22) Filed: Sep. 23, 2024

(51) Int. Cl. C30B 25/14; C23C 16/455; C23C 16/46; C30B 25/08; C30B 25/10; H01L 21/67

(52) U.S. Cl. CPC C30B 25/14; C23C 16/45591; C23C 16/46; C30B 25/08; C30B 25/10; H10P 72/0402

(57) ABSTRACT

The present disclosure relates to flow guide arrangements for gas activation and gas distribution, and related chamber kits, methods, and processing chambers. In one or more embodiments, a processing chamber includes a chamber body at least partially defining an internal volume, one or more heat sources operable to heat the internal volume, a substrate support disposed in the internal volume, and one or more inlet openings configured to direct a gas across a gas flow path over the substrate support and to one or more exhaust outlets. The processing chamber includes a flow guide disposed in the internal volume. The flow guide includes a first guide block, a second guide block disposed opposite the first guide block with respect to the gas flow path, and a flange connecting the first guide block and the second guide block.

### BACKGROUND

### Field

The present disclosure relates to flow guide arrangements for gas activation and gas distribution, and related chamber kits, methods, and processing chambers.

### Description of the Related Art

Semiconductor substrates are processed for a wide variety of applications, including the fabrication of integrated devices and micro-devices. One method of processing substrates includes depositing a material, such as a dielectric material or a semiconductor material, on an upper surface of the substrate. The material may be deposited in a lateral flow chamber by flowing a process gas parallel to the surface of a substrate positioned on a support, and thermally decomposing the process gas to deposit a material from the gas onto the substrate surface.

However, gas flow can be limited with respect to adjustability and uniformity. As an example, processing can result in insufficient deposition or excessive deposition near an outer edge of the substrate, which can cause film thickness non-uniformity and negatively affect device performance. As another example, gases can be exhausted in a non-uniform manner.

Therefore, a need exists for improved process chamber components and processing chambers.

### SUMMARY

The present disclosure relates to flow guide arrangements for gas activation and gas distribution, and related chamber kits, methods, and processing chambers.

In one or more embodiments, a processing chamber includes a chamber body at least partially defining an internal volume, one or more heat sources operable to heat the internal volume, a substrate support disposed in the internal volume, and one or more inlet openings configured to direct a gas across a gas flow path over the substrate support and to one or more exhaust outlets. The processing chamber includes a flow guide disposed in the internal volume. The flow guide includes a first guide block, a second guide block disposed opposite the first guide block with respect to the gas flow path, and a flange connecting the first guide block and the second guide block.

In one or more embodiments, a flow guide for disposition in a processing chamber. The flow guide includes a first guide block and a second guide block disposed opposite the first guide block. Inner surfaces of the first guide block and the second guide block define a flow opening therebetween. The flow guide includes a flange connecting the first guide block and the second guide block. The flange bounds a side of the flow opening. The flange, the first guide block, and the second guide block respectively include one or more opaque outer surfaces.

In one or more embodiments, a method of processing substrates including heating a substrate positioned on a substrate support and flowing one or more process gases. The flowing includes flowing the one or more process gases over the substrate to process the substrate, flowing the one or more process gases between a pair of blocks, and flowing the one or more process gases over an opaque surface of a flange extending between the pair of blocks.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial schematic side cross-sectional view of a processing chamber, according to one or more embodiments.

FIG. 2 is a schematic partial top view of the substrate support, the substrate, the flow guide, and the exhaust block shown in FIG. 1, according to one or more embodiments.

FIG. 3 is a schematic partial cross-sectional view, along Section A-A, of the first and second guide blocks shown in FIG. 2, according to one or more embodiments.

FIG. 4 is a schematic partial cross-sectional view, along Section B-B, of the flange and the exhaust block shown in FIG. 2, according to one or more embodiments.

FIG. 5 is a schematic partial cross-sectional view, along Section C-C, of the exhaust block shown in FIG. 4, according to one or more embodiments.

FIG. 6 is a schematic front view of the exhaust block shown in FIG. 5, according to one or more embodiments.

FIG. 7 is a schematic front view of the exhaust block having an exhaust opening, according to one or more embodiments.

FIG. 8 is a schematic front view of the exhaust block having an exhaust opening, according to one or more embodiments.

FIG. 9 is a schematic partial perspective view of the flow guide, according to one or more embodiments.

FIG. 10 is a schematic block diagram view of a method of substrate processing for semiconductor manufacturing, according to one or more embodiments.

FIG. 11 is a partial schematic side cross-sectional view of a processing chamber, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to flow guide arrangements for gas activation and gas distribution, and related chamber kits, methods, and processing chambers.

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

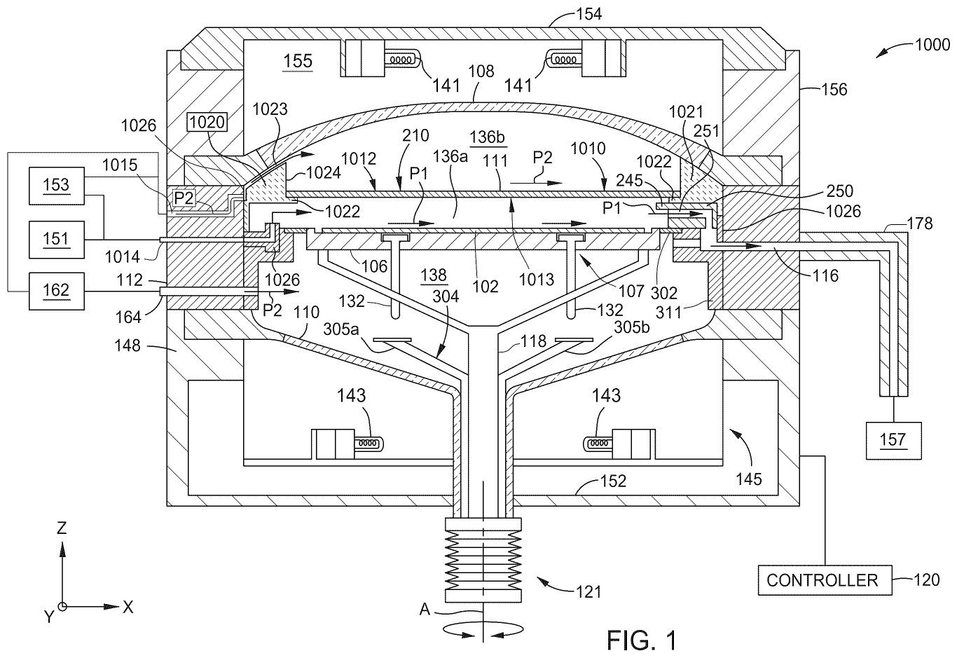

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. In one or more embodiments, the processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper plate 108 (such as an upper window and/or an upper dome), a lower plate 110 (such as a lower window and/or a lower dome), and one or more heat sources 141, 143 operable to heat the internal volume. In one or more embodiments, the one or more heat sources 141, 143 include a plurality of upper heat sources 141 and a plurality of lower heat sources 143. As shown, a controller 120 is in communication with the processing chamber 100 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 106 is disposed between the upper plate 108 and the lower plate 110. The substrate support 106 includes a support face that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 100. The plurality of lower heat sources 143 are disposed between the lower plate 110 and a floor 152. The plurality of lower heat sources 143 form a portion of a lower heat source module 145. In one or more embodiments, the upper plate 108 is an upper dome and is formed of an energy transmissive material, such as quartz. In one or more embodiments, the lower plate 110 is a lower dome and is formed of an energy transmissive material, such as quartz. A pre-heat ring 302 is disposed outwardly of the substrate support 106. A stop 304 includes a plurality of arms 305a, 305b that each include a lift pin stop on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed.

A chamber kit 1010 includes a plate apparatus 210. The plate apparatus 210 includes an isolation plate 111 having a first outer face 1012 and a second outer face 1013 opposing the first outer face 1012. The second outer face 1013 faces the substrate support 106. The chamber body includes a first liner 1020 and a second liner 311. The second liner 311 is disposed below the first liner 1020. The pre-heat ring 302 is supported on a ledge of the second liner 311. The first liner 1020 includes a curved section 1021 (e.g., an annular section). One or more inlet openings 1023 extending to an inner surface 1024 of the curved section 1021 are on a first side of the first liner 1020. The one or more inlet openings 1023 can be between the first liner 1020 and the upper plate 108. The first liner 1020 includes one or more ledges 1022 sized and shaped to support an outer region of the plate apparatus 210.

In the embodiment shown in FIG. 1, a lowermost end of the plate apparatus 210 is aligned above a lowermost end of the first liner 1020. In one or more embodiments, as shown in FIG. 1, the lowermost end of the plate apparatus 210 is part of the second outer face 1013, and the lowermost end of the first liner 1020 is part of an extension.

At least part of the plate apparatus 210 is in the shape of a disc, and at least part of the curved section 1021 is in the shape of a ring. It is contemplated, however, that the plate apparatus 210 and/or the curved section 1021 can be in the shape of a rectangle, or other geometric shapes. The plate apparatus 210 at least partially fluidly isolates an upper portion 136b of an internal volume from a lower portion 136a of the internal volume. The lower portion 136a is a processing volume. The plate apparatus 210 at least partially defines the processing volume between the plate apparatus 210 and the substrate support 106.

The flow module 112 (which can define at least part of one or more sidewalls of the processing chamber 1000) includes one or more first gas inlets 1014 in fluid communication with the lower portion 136a (e.g., the processing volume) of the internal volume. The flow module 112 includes one or more second inlet openings 1015 in fluid communication with the upper portion 136b of the internal volume. The one or more first gas inlets 1014 are in fluid communication with one or more flow gaps between the first liner 1020 and the second liner 311. One or more inject blocks 1026 having one or more flow openings formed therein can be disposed in one or more flow gaps between the first liner 1020 and the second liner 311. The one or more second inlet openings 1015 are in fluid communication with the one or more inlet openings 1023 above the first liner 1020. The first gas inlets 1014 are fluidly connected to one or more process gas sources 151 and one or more cleaning gas sources 153. The purge gas inlet(s) 164 are fluidly connected to one or more purge gas sources 162.

One or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases and/or etching gases supplied using the one or more cleaning gas sources 153 can include one or more of hydrogen and/or chlorine (such as hydrochloric acid (HCl)). In one or more embodiments, the one or more process gases include silicon hydrides (such as one or more silanes and/or one or more chlorinated silanes), germanium (such as germane (GeH₄)), boron (such as diborane (B₂H₆)), and/or phospine (PH₃).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

In the processing chamber 1000, an exhaust block 250 and a flange 245 of a flow guide 230 are disposed on an opposite side of the lower portion 136a relative to the one or more inject blocks 1026. The exhaust block 250 includes one or more exhaust openings 251.

During a deposition operation (e.g., an epitaxial growth operation), the one or more process gases P1 flow through the one or more first gas inlets 1014, through the one or more gaps, and into the lower portion 136a to flow horizontally over the substrate support 106 and the substrate 102 and toward the one or more gas exhaust outlets 116. The one or more process gases P1 flow through the one or more exhaust openings 251 of the exhaust block 250 after flowing over the substrate 102 and under the flange 245. In one or more embodiments the flange 245 is an eaves or a rim that hangs between the guide blocks 231, 236.

During the deposition operation, one or more purge gases P2 flow through the one or more second inlet openings 1015, through the one or more inlet openings 1023 of the first liner 1020, and into the upper portion 136b. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through exhaust gaps between the first liner 1020 and the second liner 311, through the exhaust block 250, and through the one or more gas exhaust outlets 116. The one or more purge gases P2 can be exhausted in a variety of manners. For example, the one or more purge gases P2 can be exhausted through the same exhaust gaps between the first liner 1020 and the second liner 311, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The present disclosure also contemplates that one or more purge gases P2 can be supplied to the purge volume 138 (through the plurality of purge gas inlets 164) during the deposition operation, and exhausted from the purge volume 138.

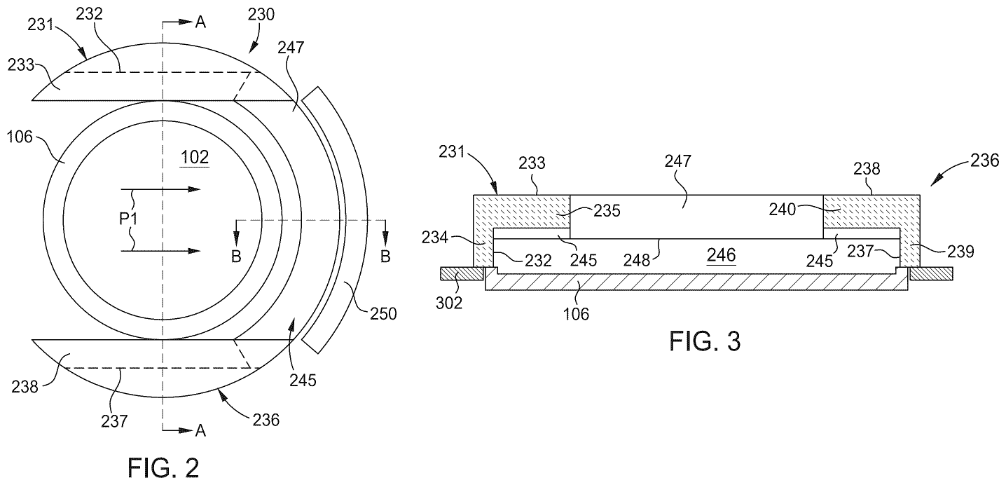

FIG. 2 is a schematic partial top view of the substrate support 106, the substrate 102, the flow guide 230, and the exhaust block 250 shown in FIG. 1, according to one or more embodiments.

The flow guide 230 includes a first guide block 231, a second guide block disposed opposite the first guide block 231 with respect to the gas flow path of the one or more process gases P1 in the lower portion 136a (e.g., the processing volume), and the flange 245. The flange 245 connects the first guide block 231 and the second guide block 236. The flange 245 extends arcuately between the first guide block 231 and the second guide block 236.

The flange 245, the first guide block 231, and the second guide block 236 respectively include one or more opaque outer surfaces. The one or more opaque outer surfaces can include for example, an inner surface 232 (e.g., a planar inner surface) of the first guide block 231, an upper surface 233 of the first guide block 231, an inner surface 237 (e.g., a planar inner surface) of the second guide block 236, an upper surface 238 of the second guide block 236, an upper surface 247 of the flange 245, and/or a lower surface 248 of the flange 245. The present disclosure contemplates that all outer surfaces of the flange 245, the first guide block 231, and the second guide block 236 can be opaque.

The present disclosure contemplates that at least part of the inner surface 232 of the first guide block 231 would be visible in FIG. 1, however the first guide block 231 is not shown in FIG. 1 for visual clarity purposes.

FIG. 3 is a schematic partial cross-sectional view, along Section A-A, of the first and second guide blocks 231, 236 shown in FIG. 2, according to one or more embodiments.

End surfaces of the flange 245 can be seen in FIG. 3. The first guide block 231 and the second guide block 236 respectively include a wall section 234, 239 including the inner surface 232, 237 and a roof section 235, 240 extending radially inwardly relative to the wall section 234, 239. In the implementation shown, the flange 245 is coupled to lower surfaces of the roof sections 235, 240 and/or the inner surfaces 232, 237 of the wall sections 234, 239. The present disclosure contemplates that the flange 245 can be coupled to the upper surfaces 233, 238. The flange 245 is aligned above at least part of the inner surfaces 232, 237 of the first guide block 231 and the second guide block 236. The inner surfaces 232, 237 define a flow opening 246 therebetween. In one or more embodiments, the flow opening 246 is a rectangular flow opening. The flange 245 extends over the flow opening 246. In one or more embodiments, the first guide block 231 and the second guide block 236 are supported at least partially on the substrate support 106. In one or more embodiments, the first guide block 231 and the second guide block 236 are supported at least partially on the pre-heat ring 302 disposed outwardly of the substrate support 106.

The first guide block 231, the second guide block 236, and the flange 245 respectively includes an opaque material. In one or more embodiments, the opaque material includes silicon carbide (SiC). Other materials are contemplated for the opaque material, such as opaque quartz (e.g. white quartz, or grey quartz, clear quartz impregnated with Si particles or SiC particles, and/or black quartz), graphite coated with SiC, and/or one or more ceramics (such as alumina (aluminum oxide (Al₂O₃)), aluminum nitride (AlN), silicon nitride (Si₃N₄), Boron Nitride (BN), and/or Boron Carbide (B₄C))). In one or more embodiments, the first guide block 231, the second guide block 236, and the flange 245 respectively are formed of SiC or graphite coated with SiC. In one or more embodiments, the opaque material has an average surface roughness (Ra) that is at least 0.5 micron up to 50 microns. In one or more embodiments, the average surface roughness is within a range of 2 microns to 20 microns. In one or more embodiments, the opaque material has an atomic structure that is non-crystalline (e.g., amorphous or polymorphous). In one or more embodiments, the opaque material has an atomic structure of 3C (e.g., 3C—SiC). In one or more embodiments, the atomic structure is 4H (e.g., 4H—SiC), or 6H (e.g., 6H—SiC).

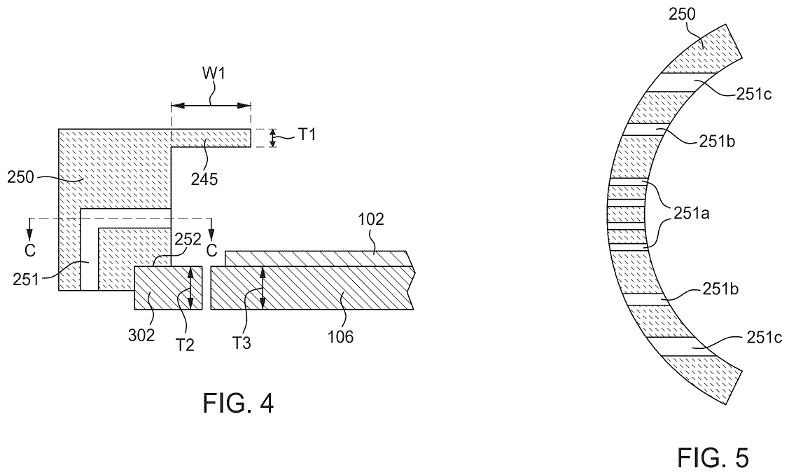

FIG. 4 is a schematic partial cross-sectional view, along Section B-B, of the flange 245 and the exhaust block 250 shown in FIG. 2, according to one or more embodiments.

The exhaust block 250 is disposed radially outwardly of the flange 245. The exhaust block 250 can include the same opaque material as described above. For example, the exhaust block 250 can be formed of SiC or graphite coated with SiC. The exhaust block 250 can include a transparent material, such as transparent quartz. For example, the exhaust block 250 can be formed of the transparent material. The flange 245 is aligned above the one or more exhaust openings 251. In one or more embodiments, the flange 245 has a rectangular cross-section extending between the first guide block 231 and the second guide block 236. Other cross-sections are contemplated.

The exhaust block 250 can abut against the flange 245, can be spaced from the flange 245 (as shown in FIG. 2) or can be coupled to the flange 245 (as shown in FIG. 4). For example, the exhaust block 250 can be integrally formed with the flange 245 or can be welded or fused to the flange 245. The flange 245 includes a thickness T1 and a width W1. The thickness T1 is within a range of 3.0 mm to 4.0 mm. Other values are contemplated. The width W1 is larger than the thickness T1. For example, the width W1 can be at least double the thickness T1. Other values are contemplated. The thickness T1 of the flange 245 can be about the same (such as within a difference of 10% or less) as a thickness T2 of the pre-heat ring 302 and/or a thickness T3 of the substrate support 106.

FIG. 5 is a schematic partial cross-sectional view, along Section C-C, of the exhaust block 250 shown in FIG. 4, according to one or more embodiments.

The one or more exhaust openings 251 include a plurality of exhaust openings 250a-250c spaced from each other along a length (such as an arcuate length) of the exhaust block 250. The exhaust openings 250a-250c have an increasing size gradient that increases in a direction outwardly relative to a center of the exhaust block 250. The increasing size gradient can involve an increase in a cross-sectional area and/or a dimension (such as a diameter) of the exhaust openings 250a-250c.

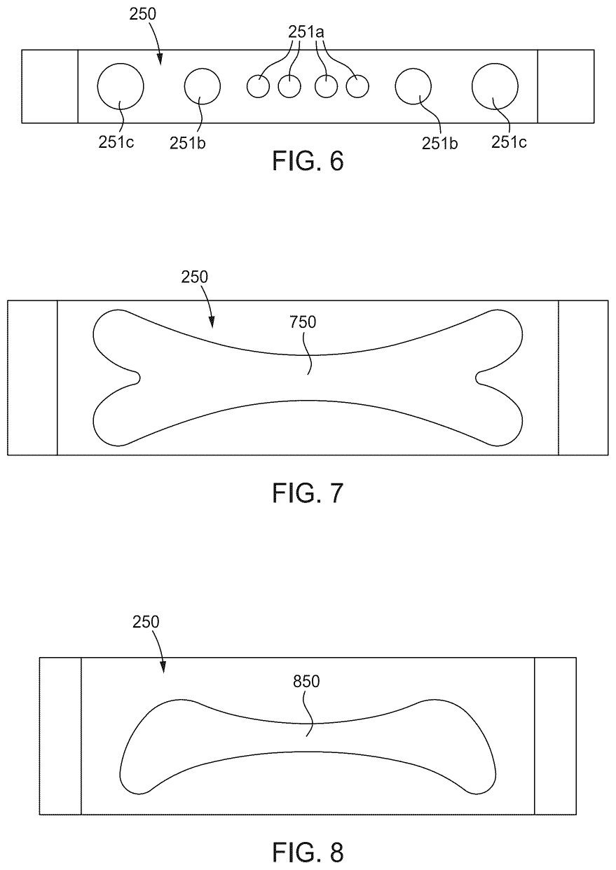

FIG. 6 is a schematic front view of the exhaust block 250 shown in FIG. 5, according to one or more embodiments.

FIG. 7 is a schematic front view of the exhaust block 250 having an exhaust opening 750, according to one or more embodiments.

The exhaust opening 750 can have the shape, for example, of a dog bone.

FIG. 8 is a schematic front view of the exhaust block 250 having an exhaust opening 850, according to one or more embodiments.

The exhaust opening 850 can have the shape, for example, of an irregular letter “M.” The exhaust opening 750 and the exhaust opening 850 respectively have an increasing size gradient that increases in a direction outwardly relative to a center of the exhaust block 250. The increasing size gradient can involve an increase in a cross-sectional area and/or a dimension (such as a height) of the respective exhaust opening 750, 850. The increasing size gradient can shift to level off or decrease at locations adjacent to the two ends of the respective exhaust opening 750, 850.

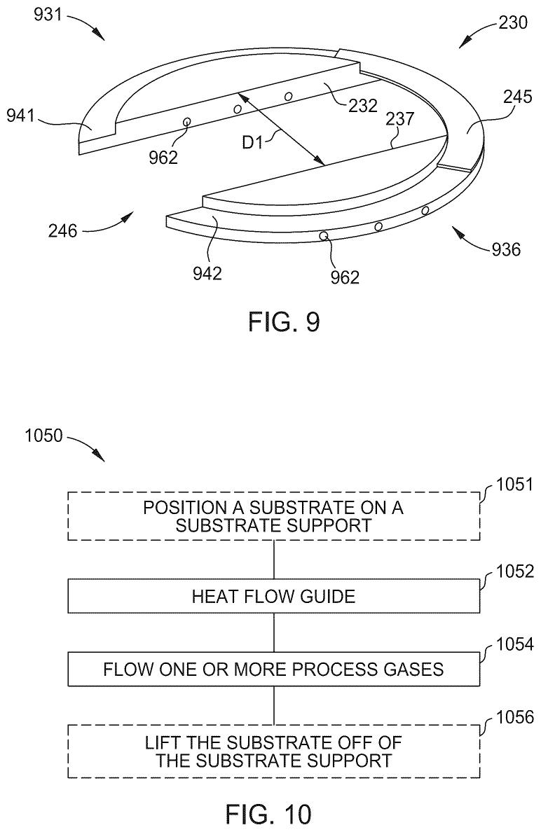

### FIG. 9 is a schematic partial perspective view of the flow guide 230, according to one or more embodiments.

In the implementation shown in FIG. 9, a pair of flow guide blocks 931, 936 are used, which respectively include one or more recessed surfaces 941, 942. The flange 245 abuts against and/or is coupled to the one or more recessed surfaces 941, 942. The guide blocks 231, 236 can be disposed in the processing volume 136a.

The blocks 931, 936 are spaced from each other along a first direction D1. In one or more embodiments, the direction D1 is perpendicular to the direction of gas flow in the processing chamber 1000 of FIG. 1 in order to guide process gas P1 within the rectangular flow opening 246 defined between the inner surface 232 of the first guide block 931 and the inner surface 237 of the second guide block 936. It is contemplated that the first and second guide blocks 931, 936 may include actuating supports configured to mechanically move the plate apparatus 210 up and down.

As shown in FIG. 9, the blocks 931, 936 can include one or more flow openings 962 (e.g., perforations) extending radially to the processing volume 136a. The flow openings 962 can be omitted from the first guide block 931 and/or the second guide block 936. A gas flow of the one or more process gases P1 can flow into the processing volume 136a through the one or more flow openings 962.

FIG. 10 is a schematic block diagram view of a method 1050 of substrate processing for semiconductor manufacturing, according to one or more embodiments.

Optional operation 1051 includes positioning a substrate on a substrate support in a processing volume of a processing chamber. In one or more embodiments, the positioning includes moving a substrate support and/or a plurality of lift pins relative to each other to land the substrate on the substrate support.

Operation 1052 of the method 1050 includes heating the flow guide 230. For example, the flange 245, the first guide block 231, and/or the second guide block 236 can be heated. The exhaust block 250 can also be heated. The heating can also heat the substrate support and/or the substrate in the processing volume to a target temperature.

Operation 1054 includes flowing one or more process gases between the substrate support and a plate apparatus (such as the plate apparatus 210) spaced from the substrate support. The one or more process gases flow over the substrate to process the substrate. For example, the process gases can form (e.g. deposit) one or more layers on the substrate or can etch the substrate. The process gases can flow between the guide blocks 231, 236, under the flange 245, and through the exhaust block 250. The process gases can flow over an opaque surface of the flange 245 and/or over opaque surfaces of the guide blocks 231, 236. In one or more embodiments, the one or more process gases flow over the flange 245 after flowing over the substrate and between the pair of blocks 231, 236. The heating of operation 1012 can include directing energy toward the opaque surface(s) of the flange 245, the first guide block 231, the second guide block, and/or the exhaust block 250. In one or more embodiments, the substrate is omitted from the substrate support and the one or more process gases clean the processing chamber.

Optional operation 1056 includes lifting the substrate off of the substrate support. In one or more embodiments, the lifting includes moving a substrate support and/or a plurality of lift pins relative to each other to engage the substrate with the lift pins and lift the substrate.

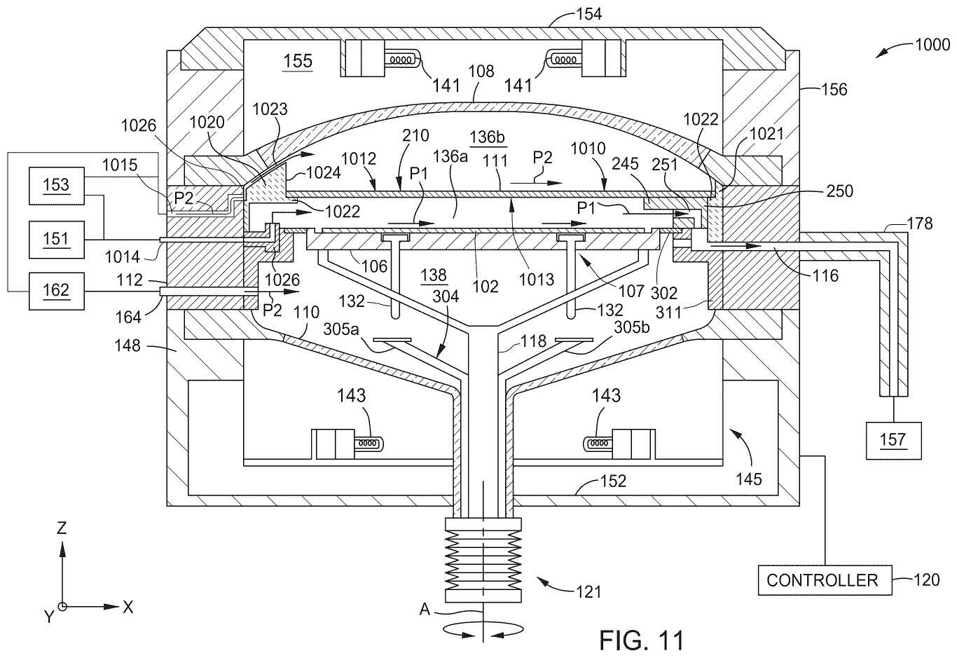

FIG. 11 is a partial schematic side cross-sectional view of a processing chamber 1100, according to one or more embodiments. The processing chamber 1100 is similar to the processing chamber 1000 shown in FIG. 1, and includes one or more aspects, features, components, properties, and/or operations thereof.

In the implementation shown in FIG. 11, the exhaust block 250 and the flange 245 are disposed radially inwardly of the one or more ledges 1022 of the upper liner 1020. The exhaust block 250 and/or the flange 245 can contact the second outer face 1013 of the plate 111.

Benefits of the present disclosure include processing adjustability (such as temperature adjustability for example of an edge region of a substrate, and/or adjustability of gas flow); adjustability of gas flow patterns and velocities; adjustability of gas flow speed; adjustability of gas residence times; adjustability of gas activation without increasing chamber sizes and footprints; thermal uniformity; gas flow uniformity (such as across substrate zones). As an example, a more uniform flow of gases can be facilitated for gas flow adjacent to an exhaust area of processing chambers. As another example, deposition at an edge region of a substrate can be enhanced with reduced or eliminated chances of over-deposition. For example, the subject matter can be used to reliably activate different gases (such as dopant gases (e.g., diborane) and deposition gases (e.g., a dichlorosilane)) having different activation temperatures. As a further example, deposition is reduced on exhaust chamber components, such as the gas exhaust outlets 116.

Benefits also include enhanced dopant concentrations; enhanced deposition thicknesses; enhanced selectivity adjustability; and increased throughput and efficiency; and reduced chamber downtime. As an example, certain gases can be reliably activated for low temperature operations (such as temperatures less than 650 degrees Celsius, for example 550 degrees Celsius, or 450 degrees Celsius or less, such as 400 degrees Celsius or less).

It is contemplated that one or more aspects disclosed herein may be combined. As an example, one or more aspects, features, components, operations and/or properties of the processing chamber 1000, the plate apparatus 210, the flow guide 230, the first guide block 231, the second guide block 236, the first guide block 931, the second guide block 926, the flange 245, the exhaust block 250, the exhaust openings 250a-250c, the exhaust opening 750, the exhaust opening 850, the method 1010, and/or the processing chamber 1100 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

1. A processing chamber, comprising:
a chamber body at least partially defining an internal volume;
one or more heat sources operable to heat the internal volume;
a substrate support disposed in the internal volume;
one or more inlet openings configured to direct a gas across a gas flow path over the substrate support and to one or more exhaust outlets; and
a flow guide disposed in the internal volume, the flow guide comprising:
a first guide block,
a second guide block disposed opposite the first guide block with respect to the gas flow path, and
a flange connecting the first guide block and the second guide block.

2. The processing chamber of claim 1, wherein the flange, the first guide block, and the second guide block respectively comprise one or more opaque outer surfaces.

3. The processing chamber of claim 1, wherein the flange is aligned above at least part of planar inner surfaces of the first guide block and the second guide block, the planar inner surfaces defining a rectangular flow opening therebetween.

4. The processing chamber of claim 3, wherein the flange extends over the rectangular flow opening.

5. The processing chamber of claim 1, wherein the flange extends arcuately between the first guide block and the second guide block.

6. The processing chamber of claim 1, wherein the first guide block and the second guide block are supported at least partially on a pre-heat ring disposed outwardly of the substrate support.

7. The processing chamber of claim 1, further comprising an exhaust block disposed radially outwardly of the flange, the exhaust block comprising one or more exhaust openings.

8. The processing chamber of claim 7, wherein the one or more exhaust openings having an increasing size gradient that increases in a direction outwardly relative to a center of the exhaust block.

9. The processing chamber of claim 7, wherein the flange is aligned above the one or more exhaust openings.

10. The processing chamber of claim 1, wherein the first guide block, the second guide block, and the flange respectively comprise silicon carbide (SiC).

11. The processing chamber of claim 10, wherein the first guide block, the second guide block, and the flange respectively are formed of graphite coated with SiC.

12. A flow guide for disposition in a processing chamber, comprising:
a first guide block;
a second guide block disposed opposite the first guide block, inner surfaces of the first guide block and the second guide block defining a flow opening therebetween; and
a flange connecting the first guide block and the second guide block, the flange bounding a side of the flow opening, and the flange, the first guide block, and the second guide block respectively comprising one or more opaque outer surfaces.

13. The flow guide of claim 12, wherein a thickness of the flange is within a range of 3.0 mm to 4.0 mm, and a width of the flange is larger than the thickness.

14. The flow guide of claim 12, wherein the flange has a rectangular cross-section extending between the first guide block and the second guide block.

15. The flow guide of claim 12, wherein the first guide block, the second guide block, and the flange respectively are formed of graphite coated with SiC.

16. The flow guide of claim 12, wherein the flange is aligned above at least part of the inner surfaces of the first guide block and the second guide block.

17. The flow guide of claim 12, wherein the flange extends arcuately between the first guide block and the second guide block.

18. A method of processing substrates, comprising:
heating a substrate positioned on a substrate support; and
flowing one or more process gases, comprising:
flowing the one or more process gases over the substrate to process the substrate,
flowing the one or more process gases between a pair of blocks, and
flowing the one or more process gases over an opaque surface of a flange extending between the pair of blocks.

19. The method of claim 18, wherein the pair of blocks comprise opaque surfaces, and the heating includes directing energy toward the opaque surface of the flange.

20. The method of claim 18, wherein the one or more process gases flow over the flange after flowing over the substrate and between the pair of blocks, and the pair of blocks and the flange respectively comprise silicon carbide (SiC).
